(19) United States
(12) Patent Application Publication
(10) Pub. No.: US 2024/0242964 A1
(43) Pub. Date: Jul. 18, 2024

(54) CRYSTALLINE STRONTIUM TITANATE (STO) AND METHOD FOR DEPOSITION OF THE STO ON A SUBSTRATE

(71) Applicant: SUPERQ TECHNOLOGIES INDIA PRIVATE LIMITED, Bangalore (IN)

(72) Inventors: SUBHASH KANNAPPA MANOHARAN, Bangalore (IN); MANJUNATH GANGAIAH, Ramnagara (IN); PURNIMA SETHI JOSAN, Bangalore (IN); BALAJI SOMPALLE, Delhi (IN); PINAKIN MANSUKHLAL PADALIA, Rajkot (IN); AMLAN MUKHERJEE, Durgapur (IN); NAGENDRA NAGARAJA, Bangalore (IN)

(21) Appl. No.: 18/498,438

(22) Filed: Oct. 31, 2023

(30) Foreign Application Priority Data
Sep. 8, 2022 (IN) 202241051433

(51) Int. Cl. H01L 21/02; C23C 14/08; C23C 14/35; C23C 14/58; H01J 37/34

(52) U.S. Cl. CPC H01L 21/02266; C23C 14/083; C23C 14/35; C23C 14/5806; H01J 37/3405; H01L 21/02197; H01J 2237/332

(57) ABSTRACT

The embodiments herein provide a Crystalline Strontium Titanate (STO) and a method for deposition of the STO on a silicon substrate. The embodiments herein utilize radio-frequency (RF) magnetron sputtering to grow crystalline pure phase Strontium Titanate SrTiO₃ (STO) with single orientation upon a surface of oriented Silicon (Si) substrates followed by annealing at 800° C. for 1 hour in ambient conditions. Furthermore, the embodiments herein completely eliminates the buffer layer which is generally needed beneath the STO thin films, making the deposition of STO films on silicon substrates much more cost-effective than the existing method. Hence a single crystal STO film is directly obtained on the silicon substrate at the end of the process.

### CROSS-REFERENCE TO RELATED APPLICATIONS

The present application claims the priority of the Indian Provisional Patent Application (PPA) with Ser. No. 20/224,1051433 filed on Sep. 8, 2022, subsequently postdated by two months to Nov. 8, 2022 with the title “CRYSTALLINE STRONTIUM TITANATE (STO) AND METHOD FOR DEPOSITION OF THE STO ON A SILICON SUBSTRATE”. The contents of the abovementioned Application are included in entirety as reference herein.

### BACKGROUND

### Technical Field

The embodiments herein are generally related to the field of material science. The embodiments herein are particularly related to the fabrication process for depositing crystalline thin film oxides. The embodiments herein are more particularly related to the deposition of crystalline strontium titanate (STO) on substrates such as silicon without any buffer layer between the STO and silicon substrate.

### Description of the Related Art

Crystalline solids exhibit a highly ordered arrangement of their constituent particles at the microscopic level. Such ordered structures have certain advantages over amorphous solids where there is no ordered structure at the microscopic level. In the area of microfabrication, crystalline oxide thin films on silicon have attracted considerable attention in recent years due to their unique properties of high dielectric constant, low leakage current, good electric tenability, and high see-beck coefficient.

Crystalline strontium titanate (SrTiO₃) is an interesting material as a building block for functional oxides with exotic properties, such as very high dielectric permittivity, very high electron mobility, superconductivity or colossal magnetoresistance, as well as piezoelectricity, pyroelectricity, and ferroelectricity. Examples include Pb(Zr,Ti)O₃, (Ba,Sr)TiO₃, LiNbO₃, BaTiO₃, CaTiO₃, Sr₁₋ₓLaₓTiO₃, La₁₋ₓSrₓMnO₃, Nd₁₋ₓSrMnO₃, etc. SrTiO₃ is itself an interesting complex dielectric material in its own right, exhibiting quantum paraelectric insulation, ferroelectricity, and superconductivity in various natural, strained, and doped forms. Moreover, the cubic perovskite crystal structure of SrTiO₃ is compatible with and can serve as a heterostructure template for many such exotic functional oxides, particularly those that take the form of ABO₃ perovskites and related layer compounds.

Furthermore, in the field of superconductivity and applications, the example is the deposition of STO as a buffer layer in the process of fabricating High-Temperature Superconducting (HTS) film on silicon substrates for designing a superconducting single photon detector. However, the process mentioned is general and can be applied to the deposition of other oxide thin films in a similar fashion. HTS-based single photon detectors are greatly affected by the lattice mismatch between the HTS films and the substrate. Moreover, there are other challenges pertaining to adhesion between the films and the performance of the superconducting films.

Besides, in existing inventions available, a buffer layer of STO is sputtered on top of the silicon substrate. The buffer layer is used to reduce such lattice mismatch or optimize the strain in the film, thereby improving the single photon detection device's performance. The choice and quality of the buffer layer also improve the critical temperature by several Kelvin (up to 10 K), critical current density, and lower residual resistivity which are some of the important parameters for designing superconducting single-photon detectors. Moreover, the buffer layer is suitably chosen to be transparent over a broad wavelength range from the visible to the near-infrared so the superconducting stack can be used for a wide variety of applications, from imaging to quantum communications and quantum computing.

In addition, STO thin films can be deposited using various techniques including atomic layer deposition (ALD), metal-organic vapor deposition (MOCVD), sol-gel process, pulsed laser deposition (PLD), and sputtering, among others. Compared to other techniques, sputtering offers wide compositional versatility, very high purity, extremely high adhesion of films, controllable deposition rate, and scalability.

Moreover, STO on silicon systems can be used as a growth substrate for the fabrication of thin films of other functional oxides in integrated optical and electrical devices. However, the quite large lattice mismatch between STO and Si (˜28%) presents a challenge for epitaxial growth. Additionally, the formation of an amorphous oxide over a silicon surface may prevent STO films from crystal growth. Previous attempts to obtain high-quality STO thin films grown directly on silicon have been unsuccessful. These STO films grown directly on silicon using various deposition techniques were usually polycrystalline with randomly oriented grains. Such randomly oriented polycrystalline films have certain limitations in various applications. Formation of various grain sizes and growth orientations and co-existence of secondary phase may cause low performance of the integrated devices. Consequently, appropriate buffer layers between STO and the silicon substrate are required for the highly oriented growth, especially for the epitaxial growth of STO thin films. In this regard, TiN and other buffer layer/bulk substrates are commonly used, which further increases the process steps and cost making the industrial realization even more costly. Earlier work indicated that the use of a single buffer layer like CeO₂ or a double buffer layer like CeO/YSZ is necessary to prepare high-quality STO (110) films on silicon (100) substrates. A complicated and precise growth process for the epitaxy of STO thin films on silicon has been presented in previous work, with great care exercised on the favorable interface stability, oxidation, and strain considerations for each stage of the growth mainly by Molecular Beam Epitaxy (MBE). Previous methods include many process steps leading to an increase in cost and are not scalable.

Hence, in view of this, there is a need for a structure and method for crystalline growth of functional oxide layers such as STO on the silicon substrate without any buffer layer, which is simpler, cost-effective, easier to handle, and without any requirement of an ultra-high vacuum environment.

The above-mentioned shortcomings, disadvantages, and problems are addressed herein, and which will be understood by reading and studying the following specification.

### OBJECTIVES OF THE EMBODIMENTS HEREIN

The primary object of the embodiments herein is to provide a Crystalline Strontium Titanate (STO) and a method for deposition of the STO on a silicon substrate.

Another object of the embodiments herein is to provide a method for depositing functional oxide layers on silicon substrates that is simple, scalable, efficient, and cost-effective for various applications.

Yet another object of the embodiments herein is to provide a method for depositing STO on a silicon substrate.

Yet another object of the embodiments herein is to provide a method for the deposition of functional oxides such as STO on the silicon substrate, that is cost-effective and scalable.

Yet another object of the embodiments herein is to provide a method for the deposition of crystalline STO on the silicon substrate without any buffer layer between the STO and the silicon substrate.

Yet another object of the embodiments herein is to provide a method for the deposition of crystalline STO on the silicon substrate and characterization of the STO thin film by X-ray diffraction.

Yet another object of the embodiments herein is to provide a method for the deposition of crystalline STO on the silicon substrate and measuring the surface roughness of the STO films using an atomic force microscope (AFM).

Yet another object of the embodiments herein is to provide a method for the deposition of crystalline STO on the silicon substrate and studying depth profiles and the chemical binding structures of the STO films using X-ray photoelectron spectroscopy (XPS).

These and other objects and advantages of the present invention will become readily apparent from the following detailed description taken in conjunction with the accompanying drawings.

### SUMMARY

The following details present a simplified summary of the embodiments herein to provide a basic understanding of the several aspects of the embodiments herein. This summary is not an extensive overview of the embodiments herein. It is not intended to identify key/critical elements of the embodiments herein or to delineate the scope of the embodiments herein. Its sole purpose is to present the concepts of the embodiments herein in a simplified form as a prelude to the more detailed description that is presented later.

The other objects and advantages of the embodiments herein will become readily apparent from the following description taken in conjunction with the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

This Summary is provided to introduce a selection of concepts in a simplified form that is further described below in the Detailed Description. This Summary is not intended to identify key or essential features of the claimed subject matter, nor is it intended to be used as an aid in determining the scope of the claimed subject matter.

The various embodiments herein provide crystalline strontium titanate (STO) and a method for depositing the STO on a silicon substrate. The embodiments herein utilize radio-frequency (RF) magnetron sputtering to grow crystalline pure phase SrTiO₃ (STO) with single (110) orientation upon a surface of (100)-oriented Silicon (Si) substrates followed by annealing at 800° C. for 1 hour in ambient conditions. Furthermore, the embodiments herein completely eliminate the buffer layer which is generally needed beneath the STO thin films, making the deposition of STO films on silicon substrates much more cost-effective than the existing method. Also, no amorphous oxide layer is found at the STO/Si interfaces at the end of the process.

According to one embodiment herein, a method of depositing a layer comprising crystalline oxide on a substrate is provided. The method comprises procuring a substrate and pre-treating the substrate with cleaning reagents before deposition of strontium oxide. The method further involves depositing the strontium oxide on the substrate using Radio Frequency (RF) magnetron sputtering in a sputtering chamber under vacuum pressure and minimal power conditions at room temperature. Furthermore, the method involves depositing the strontium oxide using RF magnetron sputtering with a noble gas at working pressure controlled by a mass flowmeter and a vacuum pump.

The method further involves depositing an amorphous layer of strontium oxide having a thickness ranging from a few nanometers to 100s of nanometers. In addition, the method involves annealing the deposited amorphous layer of strontium oxide at elevated temperatures to alter the surface morphology and surface roughness to develop a crystalline film, and further annealing the crystalline film in ambient air and atmospheric pressure to develop a crystalline oxide film.

According to one embodiment herein, the substrate is silicon. There are other alternative substrates to silicon, such as Gallium Arsenide, Gallium Nitride, and Silicon Carbide. These substrates offer different properties and advantages but for very specific applications. Gallium Arsenide (GaAs) is a semiconductor material that has high electron mobility and is particularly suited for high-frequency and high-speed electronic devices. Gallium Nitride (GaN) is another wide-bandgap semiconductor material known for its performance in high-power and high-frequency applications. Silicon Carbide (SiC) is a wide-bandgap semiconductor preferred only in high-temperature and high-power applications. Flexible Polymer-based substrates, like polyimide or PET (polyethylene terephthalate), can be used for flexible applications, but are not suited for STO deposition. Furthermore, the choice of the substrate depends on the specific requirements of the application. Each alternative substrate has its own unique properties that can provide advantages in certain scenarios. Factors like thermal properties, electrical properties, transparency, cost, and compatibility with fabrication processes play a significant role in substrate selection. Considering all the factors Silicon is the preferred substrate for STO deposition.

According to one embodiment herein, the strontium oxide is strontium titanate (STO). The cleaning reagent is piranha cleaning, a mixture of hydrogen peroxide and sulphuric acid, used to remove the impurities before further processing.

According to one embodiment herein, the pressure maintained inside the sputtering chamber is in the range of 5.0×10⁻⁶ mbar to 8.0×10⁻⁶ mbar and the power used for depositing the strontium titanate on the silicon substrate is in the range of 65 W to 75 W. Furthermore, the noble gas used during RF magnetron sputtering is argon and the working pressure of the argon gas is 9.6×10 ⁻³ mbar. Chemically inert gases are required for RF magnetron sputtering. Argon is the cheapest noble gas and offers the best momentum transfer. In addition, the sputtering gas should have a similar mass to the target atoms. Therefore, the ideal gas depends on the elements used.

According to one embodiment herein, the thickness of the amorphous layer of the strontium titanate (STO) is in the range of 79 to 80 nm. Further, the annealing is carried out at 800 degrees Celsius for one hour. The crystalline oxide film is the crystalline strontium titanate (STO) film.

According to one embodiment herein, the method is further used for silicon-based integrated circuits. The semiconductor industry has invested heavily in developing precise and repeatable fabrication processes for silicon-based substrates. This infrastructure allows for the creation of complex structures with high precision and reproducibility. Compatibility with existing CMOS Technology. Furthermore, the well-established infrastructure and manufacturing processes for silicon substrates contribute to cost-effectiveness. High-volume production and economies of scale reduce manufacturing costs.

According to one embodiment herein, a structure comprising a crystalline oxide film deposited on a substrate is provided. The structure comprises a substrate holder configured to hold a substrate in place during fabrication. The structure further comprises a strontium oxide layer to be deposited on the substrate using RF magnetron sputtering to obtain a single crystalline oxide film directly on the substrate.

According to one embodiment herein, the substrate is silicon and the strontium oxide layer is strontium titanate (STO). Further, the strontium titanate (STO) deposited on the substrate silicon is 3 inches in diameter and 3 mm in thickness.

According to one embodiment herein, the pressure maintained during the RF magnetron sputtering process is in the range of b 5.0×10⁻⁶ mbar to 8.0×10⁻⁶ mbar and the power utilized in RF magnetron sputtering process is in the range of 65 W to 75 W. In addition, the single crystalline oxide film is a crystalline strontium titanate (STO) film.

The foregoing summary is illustrative only and is not intended to be in any way limiting. In addition to the illustrative aspects, embodiments, and features described above, further aspects, embodiments, and features will become apparent by reference to the drawings and the following detailed description.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE DRAWINGS

The other objects, features and advantages will occur to those skilled in the art from the following description of the preferred embodiment and the accompanying drawings in which:

FIG. 1 illustrates a flowchart on a method for depositing crystalline Strontium Titanate

(STO) on a silicon substrate, according to an embodiment herein.

FIG. 2 illustrates an orthogonal view of a silicon substrate upon which a crystalline film of Strontium Titanate (STO) is grown or deposited, according to an embodiment herein.

FIG. 3 illustrates the X-ray diffraction (XRD) pattern of crystalline STO films on a silicon substrate, according to an embodiment herein.

FIG. 4 illustrates a cross-sectional SEM image of STO film on a silicon substrate, according to an embodiment herein.

FIG. 5 illustrates an X-ray photoelectron spectroscopy (XPS) wide spectrum of polycrystalline STO on a silicon substrate, according to an embodiment herein.

FIG. 6 illustrates a Strontium Sr 3D core-level XPS spectra of STO film deposited on a silicon substrate, according to an embodiment herein.

FIG. 7 illustrates a Titanium Ti 2p XPS spectra of titanium present in the STO film deposited on the silicon substrate, according to an embodiment herein.

FIG. 8 illustrates an oxygen 1s XPS spectra of Oxygen present in STO film deposited on silicon substrate, according to an embodiment herein.

Although the specific features of the present invention are shown in some drawings and not in others. This is done for convenience only as each feature may be combined with any or all of the other features in accordance with the present invention.

### DETAILED DESCRIPTION OF THE EMBODIMENTS HEREIN

In the following detailed description, reference is made to the accompanying drawings that form a part hereof, and in which the specific embodiments that may be practiced is shown by way of illustration. These embodiments are described in sufficient detail to enable those skilled in the art to practice the embodiments and it is to be understood that the logical, mechanical, and other changes may be made without departing from the scope of the embodiments. The following detailed description is therefore not to be taken in a limiting sense.

The foregoing of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments.

The accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings. Although the terms first, second, etc. may be used herein to describe various elements, these elements should not be limited by these terms. These terms are generally only used to distinguish one element from another.

The various embodiments herein provide crystalline strontium titanate (STO) and a method for depositing the STO on a silicon substrate. The embodiments herein utilize radio-frequency (RF) magnetron sputtering to grow crystalline pure phase SrTiO₃ (STO) with single (110) orientation upon a surface of (100)-oriented Silicon (Si) substrates followed by annealing at 800° C. for 1 hour in ambient conditions. Furthermore, the embodiments herein completely eliminate the buffer layer which is generally needed beneath the STO thin films, making the deposition of STO films on silicon substrates much more cost-effective than the existing method. Also, no amorphous oxide layer is found at the STO/Si interfaces at the end of the process.

According to one embodiment herein, a method of depositing a layer comprising crystalline oxide on a substrate is provided. The method comprises procuring a substrate and pre-treating the substrate with cleaning reagents before deposition of strontium oxide. The method further involves depositing the strontium oxide on the substrate using Radio Frequency (RF) magnetron sputtering in a sputtering chamber under vacuum pressure and minimal power conditions at room temperature. Furthermore, the method involves depositing the strontium oxide using RF magnetron sputtering with a noble gas at working pressure controlled by a mass flowmeter and a vacuum pump. The method further involves depositing an amorphous layer of strontium oxide having a thickness ranging from a few nanometers to 100 nanometers. In addition, the method involves annealing the deposited amorphous layer of strontium oxide at elevated temperatures to alter the surface morphology and surface roughness to develop a crystalline film, and further annealing the crystalline film in ambient air and atmospheric pressure to develop a crystalline oxide film.

According to one embodiment herein, the substrate is silicon. There are other alternative substrates to silicon, such as Gallium Arsenide, Gallium Nitride, and Silicon Carbide. These substrates offer different properties and advantages but for very specific applications. Gallium Arsenide (GaAs) is a semiconductor material that has high electron mobility and is particularly suited for high-frequency and high-speed electronic devices. Gallium Nitride (GaN) is another wide-bandgap semiconductor material known for its performance in high-power and high-frequency applications. Silicon Carbide (SiC) is a wide-bandgap semiconductor preferred only in high-temperature and high-power applications. Flexible Polymer-based substrates, like polyimide or PET (polyethylene terephthalate), can be used for flexible applications, but are not suited for STO deposition. Furthermore, the choice of the substrate depends on the specific requirements of the application. Each alternative substrate has its own unique properties that can provide advantages in certain scenarios. Factors like thermal properties, electrical properties, transparency, cost, and compatibility with fabrication processes play a significant role in substrate selection. Considering all the factors Silicon is the preferred substrate for STO deposition.

In addition, using silicon as a substrate for STO deposition offers numerous advantages due to its unique material properties and well-established manufacturing processes. Silicon is a semiconductor material with excellent electronic properties. This makes the silicon suitable for the fabrication of downstream electronic components and devices. The silicon has an excellent epitaxial growth and adhesion. The adhesion between silicon (Si) and strontium titanate (SrTiO3 or STO) is considerably good but also dependent on several factors including the surface treatment. Furthermore, Silicon-based substrates for STO can be fabricated at very small scales using advanced microfabrication techniques. This enables the miniaturization of electronic devices, leading to the development of smaller and more powerful technologies. Also, silicon has good compatibility with various fabrication techniques allowing for the integration of multiple components on a single substrate, which is crucial for creating multifunctional devices and systems.

According to one embodiment herein, the strontium oxide is strontium titanate (STO). The cleaning reagent is piranha cleaning, a mixture of hydrogen peroxide and sulphuric acid, used to remove the impurities before further processing.

According to one embodiment herein, the pressure maintained inside the sputtering chamber is in the range of 5.0×10⁻⁶ mbar to 8.0×10⁻⁶ mbar and the power used for depositing the strontium titanate on the silicon substrate is in the range of 65 W to 75 W. Furthermore, the noble gas used during RF magnetron sputtering is argon and the working pressure of the argon gas is 9.6×10⁻³ mbar mbar. Chemically inert gases are required for RF magnetron sputtering. Argon is the cheapest noble gas and offers the best momentum transfer. In addition, the sputtering gas should have a similar mass to the target atoms. Therefore, the ideal gas depends on the elements used.

Fundamentally, RF magnetron sputtering for depositing strontium titanate (STO) thin films is a versatile and controlled method. RF Magnetron Sputtering is a physical vapor deposition (PVD) technique in which atoms from a solid target material are dislodged by bombarding it with high-energy ions. These dislodged atoms or ions are then deposited onto a substrate like silicon to form a thin film. RF magnetron sputtering enhances the sputtering process by using a magnetic field to trap electrons near the target surface. This increases ionization efficiency and improves the overall sputtering rate and target material utilization. The magnetic field is created using permanent magnets or electromagnets located behind the target. The process of depositing STO thin films using RF magnetron sputtering typically involves following steps such as vacuum chamber preparation, substrate placement, target mounting, sputtering process, sputtering and deposition, and film growth and thickness control. During vacuum chamber preparation the process begins with evacuating the vacuum chamber to create a low-pressure environment. This is important to prevent unwanted reactions and ensure the deposition occurs in a controlled atmosphere. The substrate then is mounted on a substrate holder inside the chamber, which is the substrate placement. The substrate holder can also be equipped with heating and cooling mechanisms to control the substrate temperature during the deposition. Further, the target mounting is carried out by mounting the STO target on the magnetron sputtering system, which generates the magnetic field. Argon gas is introduced into the chamber as a working gas. In addition, a high-frequency RF power supply is applied to the target. This creates a plasma of argon ions in the vicinity of the target. The magnetic field traps electrons, causing them to spiral along magnetic field lines and gain energy. These high-energy electrons collide with argon atoms, ionizing them. The positively charged argon ions are accelerated toward the target surface. Further, the accelerated argon ions collide with the STO target, dislodging atoms from the target surface through momentum transfer. These dislodged atoms travel across the chamber and deposit onto the substrate, forming a thin film of STO. The deposition rate and film thickness are controlled by factors such as the sputtering power, gas pressure, and deposition time. Monitoring and controlling these parameters allow precise control over film thickness and quality.

Moreover, RF magnetron sputtering offers significant advantages for depositing STO thin films, such as a controlled and precise deposition process, good control over film thickness and composition, suitable for deposition on various substrate sizes and shapes, achieving high-quality films with desired properties, and compatible with automation and can be integrated into the larger manufacturing process. Furthermore, STO thin films deposited using RF magnetron sputtering find applications in various fields, including electronics, optics, and materials research. They are used in devices like capacitors, resistors, and memory devices, and as substrates for the epitaxial growth of other materials. STO thin films can also be fabricated by many other alternative depositional techniques. Chemical techniques include atomic layer deposition (ALD), metal-organic vapor deposition (MOCVD), and the sol-gel process, among others. Physical techniques include pulsed laser deposition (PLD) and magnetron sputtering. Compared to other techniques, magnetron sputtering shows many advantages, i.e., wide compositional versatility, very high purity, extremely high adhesion of films, and controllable deposition rate. Overall, RF magnetron sputtering is a preferred technique for depositing STO thin films with controlled properties, making it an important method in thin film technology.

According to one embodiment herein, the thickness of the amorphous layer of the strontium titanate (STO) is in the range of 79 to 80 nm. Further, the annealing is carried out at 800 degrees Celsius for one hour. The crystalline oxide film is the crystalline strontium titanate (STO) film.

According to one embodiment herein, the method is further used for silicon-based integrated circuits. The semiconductor industry has invested heavily in developing precise and repeatable fabrication processes for silicon-based substrates. This infrastructure allows for the creation of complex structures with high precision and reproducibility. Compatibility with existing CMOS Technology. Furthermore, the well-established infrastructure and manufacturing processes for silicon substrates contribute to cost-effectiveness. High-volume production and economies of scale reduce manufacturing costs.

According to one embodiment herein, a structure comprising a crystalline oxide film deposited on a substrate is provided. The structure comprises a substrate holder configured to hold a substrate in place during fabrication. The structure further comprises a strontium oxide layer to be deposited on the substrate using RF magnetron sputtering to obtain a single crystalline oxide film directly on the substrate.

According to one embodiment herein, the substrate is silicon and the strontium oxide layer is strontium titanate (STO). Further, the strontium titanate (STO) deposited on the substrate silicon is 3 inches in diameter and 3 mm in thickness.

Moreover, the substrate holder is a critical component in STO fabrication processes. The substrate holder in the STO process ensures precise positioning and alignment of the substrate within the deposition equipment. This is crucial for achieving consistent and repeatable results in microfabrication processes. STO substrate holders also provide stability to the Si substrate, preventing unintended movement or vibration during processing. This stability is essential for maintaining uniformity and preventing defects in the fabricated structures. Additionally, STO processes require a high degree of flatness in the substrate, and the holder helps maintain this flatness. Further, the STO substrate holder is designed to facilitate efficient heat transfer to or from the substrate. This ensures that the substrate maintains the desired temperature throughout the process, which influences the quality of the fabricated layers or patterns.

According to one embodiment herein, the pressure maintained during the RF magnetron sputtering process is in the range of 5.0×10⁻⁶ mbar to 8.0×10⁻⁶ mbar and the power utilized in RF magnetron sputtering process is in the range of 65 W to 75 W. In addition, the single crystalline oxide film is a crystalline strontium titanate (STO) film.

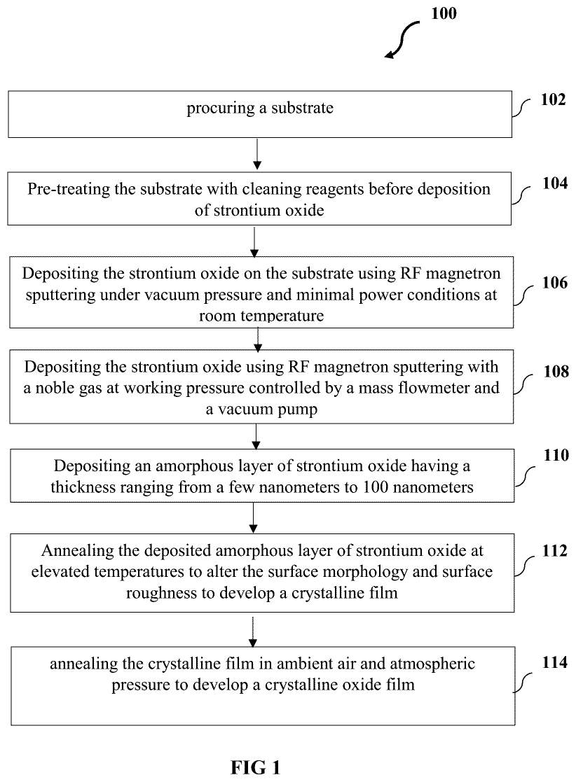

FIG. 1 illustrates a flowchart on a method for depositing crystalline Strontium Titanate (STO) on a silicon substrate, according to an embodiment herein. The method 100 comprises procuring a substrate at step 102, wherein the substrate is a silicon substrate. The method 100 further involves pre-treating the substrate with cleaning reagents before the deposition of strontium oxide at step 104. The strontium oxide is strontium titanate (STO). The cleaning reagent is piranha cleaning, a mixture of hydrogen peroxide and sulphuric acid, used to remove the impurities. The method 100 further involves depositing the strontium oxide on the substrate using Radio Frequency (RF) magnetron sputtering in a sputtering chamber under vacuum pressure and minimal power conditions at room temperature at step 106. The pressure maintained inside the sputtering chamber is in the range of 5.0×10⁻⁶ mbar to 8.0×10⁻⁶ mbar and the power used for depositing the strontium titanate on the silicon substrate is in the range of 65 W to 75 W. Furthermore, the method 100 involves depositing the strontium oxide using RF magnetron sputtering with a noble gas at working pressure controlled by a mass flowmeter and a vacuum pump at step 108. The noble gas used during RF magnetron sputtering is argon and the working pressure of the argon gas is 9.6×10⁻³ mbar. The method 100 further involves depositing an amorphous layer of strontium oxide having a thickness ranging from a few nanometers to 100s of nanometers at step 110. The thickness of the amorphous layer of the strontium titanate (STO) is in the range of 79 to 80 nm. In addition, the method 100 involves annealing the deposited amorphous layer of strontium oxide at elevated temperatures to alter the surface morphology and surface roughness to develop a crystalline film at step 112. The annealing is carried out at 800 degrees Celsius for one hour. The method 100 further involves annealing the crystalline film in ambient air and atmospheric pressure to develop a crystalline oxide film at step 114. The crystalline oxide film is the crystalline strontium titanate (STO) film.

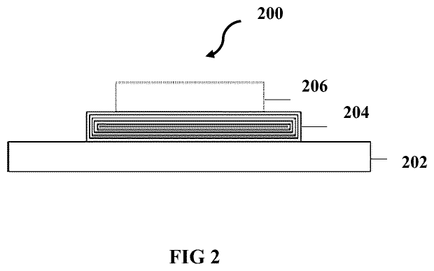

FIG. 2 illustrates an orthogonal view of a silicon substrate upon which a crystalline film of Strontium Titanate (STO) is grown or deposited, according to an embodiment herein. FIG. 2, structure 200 comprises a substrate holder 202 configured to hold a substrate 204 in place during fabrication. The silicon substrate has a crystal orientation of <100>. The structure 200 further comprises a strontium oxide layer 206 to be deposited on the substrate 204 using RF magnetron sputtering to obtain a single crystalline oxide film directly on the substrate 204. The strontium oxide layer 206 strontium titanate (STO) and the crystalline oxide film is crystalline strontium titanate (STO) film. The size of STO thin film 206 is obtained with 99.99% purity, 3 inches in diameter and 3 mm in thickness. The background pressure in the vacuum chamber during RF magnetron sputtering is in the range of 5.0×10⁻⁶ mbar to 8.0×10⁻⁶ mbar. Furthermore, the RF power is set in the range of 65 W to 75 W. After deposition, the strontium oxide layer 206 is annealed at temperatures of 800° C. in an ambient environment for one hour to obtain a single crystalline strontium titanate directly on the silicon substrate 204.

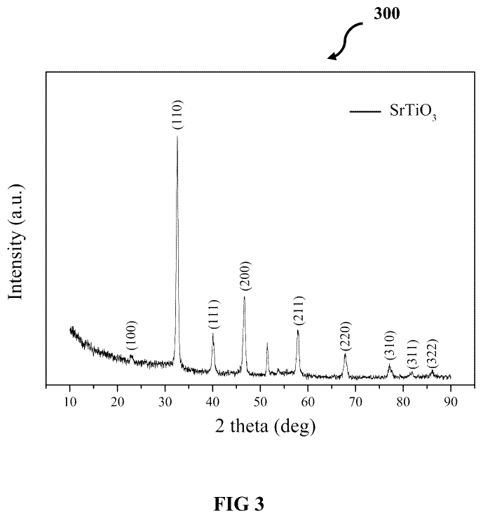

FIG. 3 illustrates the X-ray diffraction (XRD) pattern of crystalline STO films on a silicon substrate, according to an embodiment herein. With respect to FIG. 3, 300 illustrates the X-ray diffraction pattern of crystalline STO films on the silicon substrate annealed at 800° C. for 1 hour in an ambient environment. The XRD pattern 300 reveals that STO films are highly crystalline with distinct sharp peaks observed at 23.02°, 32.58°, 40.12°, 46.71°, 46.71°, 51.37°, 57.92°, 67.78°, 77.08°, 81.63°, and 86.13° for the planar reflection of (100), (110), (111), (200), (211), (220), (310), (311) and (322) respectively (ICDD 01-08-0443), which confirms the formation of pure phase STO on Si substrates. The most prominent peak obtained is at 32.58° corresponding to the crystal orientation of 110, which depicts the orientation of the deposited STO film.

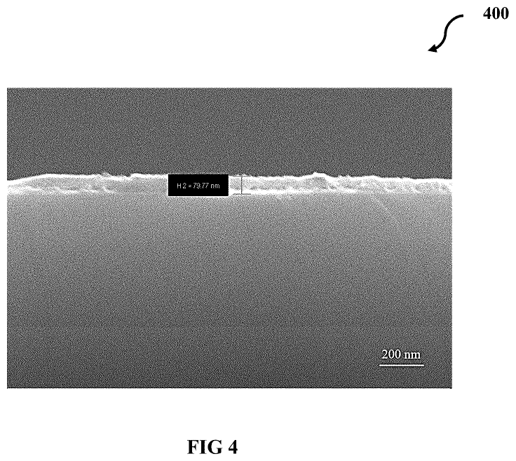

FIG. 4 illustrates a cross-sectional SEM image of STO film on a silicon substrate, according to an embodiment herein. With respect to FIG. 4 400, illustrates the cross-sectional SEM image of the crystalline STO films deposited on silicon substrate using RF sputtering and followed by annealing at 800° C. for 1 hour in an ambient environment. The FIG. 4 400, shows that the thickness of the deposited STO film is in the range of 79-80 nm which is the desired thickness for the deposition of a superconducting layer on top of the STO film for fabricating the superconducting single photon detector.

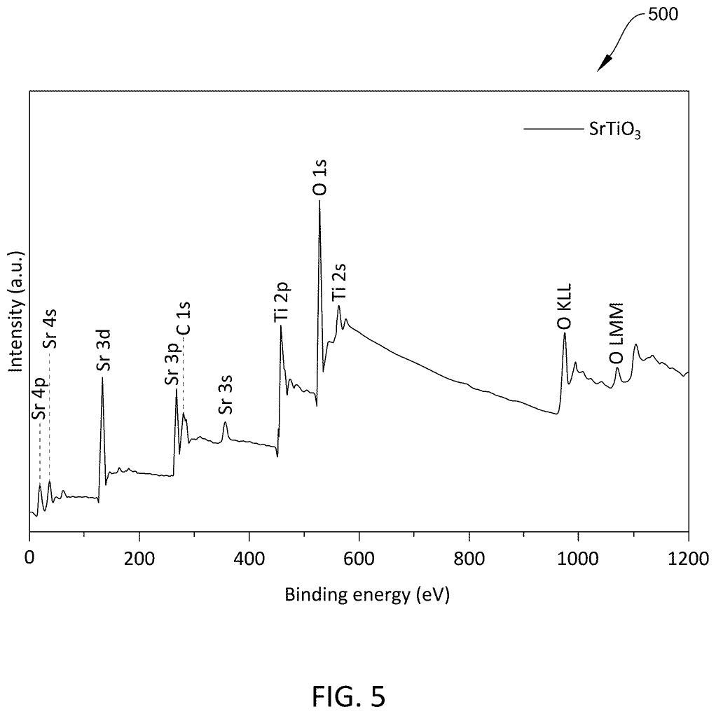

FIG. 5 illustrates an X-ray photoelectron spectroscopy (XPS) wide spectrum of polycrystalline STO on a silicon substrate, according to an embodiment herein. With respect to FIG. 5 500, illustrates an XPS Wide spectrum of polycrystalline STO. The XPS survey spectrum 500 reveals the presence of elements in the RF sputtered STO films deposited on the silicon substrate followed by annealing at 800° C. for 1 hour at an ambient environment. The binding energies appeared at around 19.71 eV, 36.71 eV, 133.71 eV, 268.71 eV, and 356. 58 eV corresponds to Sr 4p, Sr 4s, Sr 3d, Sr 3p, and Sr 3s respectively which confirms the presence of the strontium (Sr) element. The peaks at binding energies 458.71 eV and 563, 56 eV correspond to Ti 2p and Ti 2s respectively, confirming the presence of titanium (Ti) element in the deposited films. The presence of oxygen (O) element in the deposited film was affirmed by the peak at binding energy 528 eV.

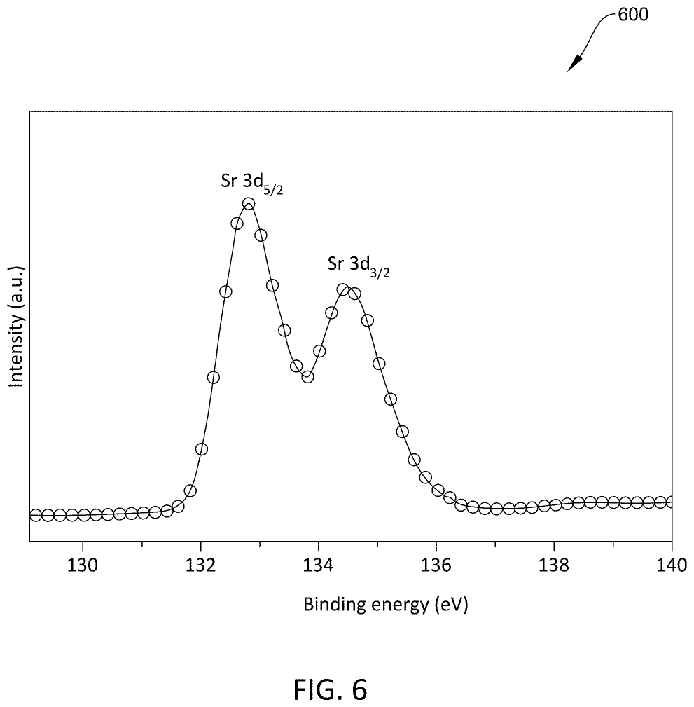

FIG. 6 illustrates a Strontium Sr 3D core-level XPS spectra of STO film deposited on a silicon substrate, according to an embodiment herein. With respect to FIG. 6 600, illustrates a Sr 3d core-level XPS Spectra of STO film deposited on silicon substrates followed by annealing at 800° C. for 1 hour in an ambient environment. The Sr 3d core-level XPS spectra of STO film 600 show the presence of two peaks at binding energies 132.8 eV and 134.5 eV, which can be assigned to Sr 3d_{5/2} and Sr 3d_{3/2} which are components of Sr 3d. The two peaks are consistent with the Sr in STO, which not only indicates that no obvious metallic Sr° appearance but also the presence of Sr in the valence state Sr²⁺ in the deposited STO films.

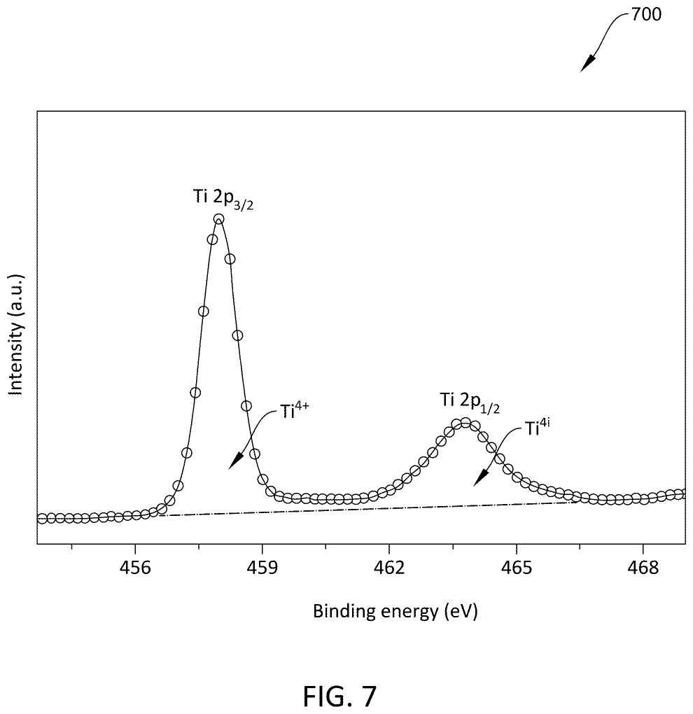

FIG. 7 illustrates a Titanium Ti 2p XPS spectra of titanium present in the STO film deposited on the silicon substrate, according to an embodiment herein. The FIG. 7 700, illustrates a Ti 2p XPS Spectra of titanium (Ti) present in the STO film deposited on silicon substrate followed by annealing at 800° C. for 1 hour at ambient environment. The Ti 2p XPS narrow spectra 700 notify the peaks at binding energies at 455.47 eV and 461.24 eV, which corresponds to the Ti 2p_{3/2} and Ti 2p_{1/2} spin-orbital electrons split in the Ti⁴⁺ state of Ti elements in the deposited STO films respectively.

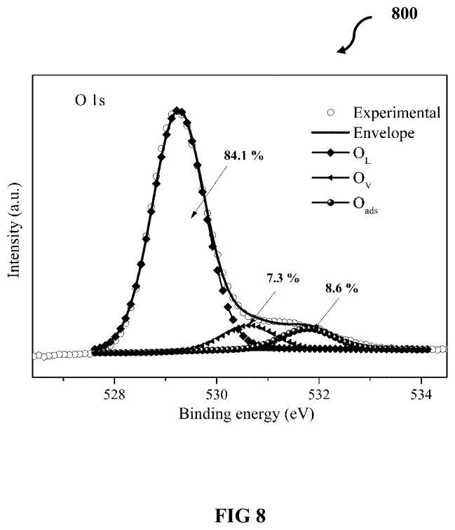

FIG. 8 illustrates an oxygen 1s XPS spectra of Oxygen present in STO film deposited on silicon substrate, according to an embodiment herein. The FIG. 8, 800 illustrates O 1s XPS Spectra of oxygen (O) present in STO film deposited on silicon substrate followed by annealing at 800° C. for 1 hour in an ambient environment. The deconvoluted O 1s spectra have three components at binding energies 529.3 eV, 530.84 eV, and 531.78 eV. The component at binding energy 529.3 eV corresponds to the oxygen anions O²⁻ in the perovskite structure of Sr²⁺ and Ti⁴⁺ ions array in the deposited STO films. The percentage of area under the curve which indicates the oxygen anions in deposited films is about 84.1%. The component at 530.84 eV corresponds to the non-stoichiometry and point defects due to oxygen vacancies. The component 531.78 eV indicates the adsorbed oxygen species.

It is also to be understood that various arrangements may be devised that, although not explicitly described or shown herein, embody the principles of the present disclosure. Moreover, all statements herein reciting principles, aspects, and embodiments of the present disclosure, as well as specific examples, are intended to encompass equivalents thereof.

While the disclosure is susceptible to various modifications and alternative forms, specific embodiment thereof has been shown by way of example in the drawings and will be described in detail above. It should be understood, however that it is not intended to limit the disclosure to the forms disclosed, but on the contrary, the disclosure is to cover all modifications, equivalents, and alternatives falling within the scope of the disclosure.

### ADVANTAGES OF THE EMBODIMENTS HEREIN

The embodiments herein provide a Crystalline Strontium Titanate (STO) and method for deposition of the STO on a silicon substrate. Among multiple oxide thin films being used in the electronic industry, STO is being used prominently due to its high dielectric constant oxide to replace silicon dioxide as a gate oxide in metal-oxide-semiconductor devices thereby finding applications in silicon-based integrated circuits. Moreover, the STO of the embodiments herein is a face-centered cubic perovskite structure and has a lattice constant of 0.3905 nm, which is closely matched to a large number of other perovskite oxides making the integration easier. Comparatively, the embodiments herein provide simpler crystalline growth and are easier to handle because it does not require an ultra-high-vacuum environment. During the experimental stage, the conditions for achieving crystalline

STO thin films on Silicon were limited to deposition conditions such as deposition temperature and oxygen pressure as well as specific growth sequences. Hence, the embodiments herein have eliminated the buffer layer and grown crystalline STO on silicon directly. Therefore, the successful growth of crystalline STO (110) films without any buffer layer is thus unusual. The embodiments herein also solve the problem of directly growing STO on Silicon without any buffer layer using RF

Sputtering. Therefore, the embodiments herein reduce the process steps and subsequently the cost of fabrication.

Moreover, the embodiments herein are not only limited to the deposition of STO. The embodiments herein can also be applied for the integration of many other functional oxide materials on silicon substrates. In particular, the (110)-oriented STO structure is chosen as it is of immense use in practical applications such as the preparation of ferroelectric-insulator-semiconductor devices, for providing a broad solution to the generic problem of polarity discontinuities at perovskite heterointerfaces and in superconducting device technology.

Although the embodiments herein are described with various specific embodiments, it will be obvious for a person skilled in the art to practice the embodiments herein with modifications.

The foregoing description of the specific embodiments will so fully reveal the general nature of the embodiments herein that others can, by applying current knowledge, readily modify and/or adapt for various applications such as specific embodiments without departing from the generic concept, and, therefore, such adaptations and modifications should and are intended to be comprehended within the meaning and range of equivalents of the disclosed embodiments.

It is to be understood that the phrases or terminology employed herein is for the purpose of description and not of limitation. Therefore, while the embodiments herein have been described in terms of preferred embodiments, those skilled in the art will recognize that the embodiments herein can be practiced with modifications. However, all such modifications are deemed to be within the scope of the claims.

What is claimed is:

1. A method (100) of depositing a layer comprising crystalline oxide on a substrate, the method comprising:
a. procuring a substrate (102);
b. pre-treating the substrate with cleaning reagents before deposition of strontium oxide (104);
c. depositing the strontium oxide on the substrate using Radio Frequency (RF) magnetron sputtering in a sputtering chamber under vacuum pressure and minimal power conditions at room temperature (106);
d. depositing the strontium oxide using RF magnetron sputtering with a noble gas at working pressure controlled by a mass flowmeter and a vacuum pump (108);
e. depositing an amorphous layer of strontium oxide of definite thickness (110); and
f. annealing the deposited amorphous layer of strontium oxide at elevated temperatures to alter the surface morphology and surface roughness to develop a crystalline film (112); and
g. annealing the crystalline film in ambient air and atmospheric pressure to develop a crystalline oxide film (114).

2. The method (100) according to claim 1, wherein the substrate is silicon.

3. The method (100) according to claim 1, wherein the strontium oxide is strontium titanate (STO).

4. The method (100) according to claim 1, wherein the cleaning reagent is piranha cleaning, a mixture of hydrogen peroxide and sulphuric acid, used to remove the impurities.

5. The method (100) according to claim 1, wherein the pressure maintained inside the sputtering chamber is in the range of 5.0×10⁻⁶ mbar to 8.0×10⁻⁶ mbar; and wherein the power used for depositing the strontium titanate on the silicon substrate is in the range of 65 W to 75 W.

6. The method (100) according to claim 1, wherein the noble gas used during RF magnetron sputtering is argon; and wherein the working pressure of the argon gas is 9.6×10⁻⁶ mbar.

7. The method (100) according to claim 1, wherein the thickness of the amorphous layer of the strontium titanate (STO) is in the range of 79 to 80 nm.

8. The method (100) according to claim 1, wherein the annealing is carried out at 800 degrees Celsius for one hour.

9. The method (100) according to claim 1, wherein the crystalline oxide film is the crystalline strontium titanate (STO) film.

10. The method (100) according to claim 1, wherein the method (100) is further used for silicon-based integrated circuits.

11. A substrate deposited with thin crystalline oxide film, the substrate comprising:
a. a substrate holder (202) configured to hold a substrate (204) in place during fabrication;
b. a strontium oxide layer (206) to be deposited on the substrate (204) using RF magnetron sputtering to obtain a single crystalline oxide film directly on the substrate (204).

12. The substrate according to claim 11, wherein the substrate is silicon.

13. The substrate according to claim 11, wherein the strontium oxide layer is strontium titanate (STO).

14. The substrate according to claim 11, wherein the strontium titanate (STO) deposited on the substrate silicon is 3 inches in diameter and 3 mm in thickness.

15. The substrate according to claim 11, wherein the pressure maintained during the RF magnetron sputtering process is in the range of 5.0×10⁻⁶ to 8.0×10⁻⁶ mbar; and wherein the power utilized in RF magnetron sputtering process is in the range of 65 W to 75 W.

16. The substrate according to claim 11, wherein the single crystalline oxide film is crystalline strontium titanate (STO) film.
